(19) United States
(12) Patent Application Publication
(10) Pub. No.: US 2024/0255576 A1
(43) Pub. Date: Aug. 1, 2024

(54) BATTERY TEMPERATURE MONITORING POINT IDENTIFICATION AND ABNORMALITY DETECTION METHOD, APPARATUS AND ELECTRONIC DEVICE

(71) Applicant: Shanghai Makesens Energy Storage Technology Co., Ltd., Shanghai (CN)

(72) Inventors: Haowen REN, Shanghai (CN); Qiong WEI, Shanghai (CN); Xiao YAN, Shanghai (CN); Enhai ZHAO, Shanghai (CN); Decheng WANG, Shanghai (CN); Yuan FENG, Shanghai (CN); Peng DING, Shanghai (CN); Weikun WU, Shanghai (CN); Fengwei TANG, Shanghai (CN)

(73) Assignee: Shanghai Makesens Energy Storage Technology Co., Ltd., Shanghai (CN)

(21) Appl. No.: 18/396,900

(22) Filed: Dec. 27, 2023

(30) Foreign Application Priority Data
Jan. 28, 2023 (CN) 202310087819.5

(51) Int. Cl. G01R 31/374; G01R 31/367; G01R 31/392

(52) U.S. Cl. CPC G01R 31/374; G01R 31/367; G01R 31/392

(57) ABSTRACT

A battery temperature monitoring point identification and abnormality detection method is provided according to the present disclosure. The method is applied to a battery module, and a temperature sensor inside the battery module is determined as a temperature monitoring point of a battery. The method includes: establishing a second-order RC equivalent circuit model of the battery in the battery module; performing parameter identification on the second-order RC equivalent circuit model to obtain an optimal parameter; obtaining distances between multiple temperature monitoring points in the battery module and the battery by using the obtained optimal parameter; and determining effectiveness of the temperature monitoring points based on the obtained distances between the temperature monitoring points and the battery. In the present disclosure, the optimal parameter is obtained by establishing the second-order RC equivalent circuit model, the distances between the temperature monitoring points and the battery are determined by using the optimal parameter, and the effectiveness of the temperature monitoring points are determined based on the obtained distribution of the distances between the temperature monitoring points and the battery. In a case of a large number of battery modules that cannot be disassembled, whether the temperature monitoring point is shifted or disconnected can be determined in a time-saving and labor-saving manner, and whether the temperature monitoring point is effective can be rapidly determined.

### CROSS-REFERENCE TO RELATED APPLICATION

This application claims priority to Chinese Patent Application No. 202310087819.5, filed on Jan. 28, 2023, which is incorporated herein by its reference in its entirety.

### FIELD

The present application relates to the technical field of batteries, and in particular to a battery temperature monitoring point identification and abnormality detection method and apparatus, and an electronic device.

### BACKGROUND

In an energy storage power station, the smallest energy storage unit is a battery module. The battery module includes different cells and multiple battery temperature monitoring points (which are also referred to as temperature sensors). However, during the use of the battery module, the battery temperature monitoring point may be shifted or loosened, causing malfunction and even failure of the battery temperature monitoring point. In order to determine in time whether the battery temperature measuring point inside the battery module is loosened or disconnected, a method for identifying a distance between the battery temperature monitoring point and the battery is needed.

### SUMMARY

In order to solve the existing technical problem, in a first aspect, a battery temperature monitoring point identification and abnormality detection method is provided according to an embodiment of the present disclosure. The method is applied to a battery module, a temperature sensor inside the battery module is determined as a temperature monitoring point of a battery, and the method includes:
establishing a second-order RC equivalent circuit model of the battery in the battery module;
performing parameter identification on the second-order RC equivalent circuit model to obtain an optimal parameter;
obtaining distances between multiple temperature monitoring points in the battery module and the battery by using the obtained optimal parameter; and
determining effectiveness of the temperature monitoring points based on an obtained distribution of the distances between the temperature monitoring points and the battery.

In a second aspect, a battery temperature monitoring point identification and abnormality detection apparatus is provided according to an embodiment of the present disclosure. The apparatus includes:
a model establishment unit, configured to establish a second-order RC equivalent circuit model of a battery in a battery module;
an identification unit, configured to perform parameter identification on the second-order RC equivalent circuit model to obtain an optimal parameter;
a distance measurement unit, configured to obtaining distances between temperature monitoring points in the battery module and the battery by using the obtained optimal parameter; and
a result unit, configured to determine effectiveness of the temperature monitoring points based on an obtained distribution of the distances between the temperature monitoring points and the battery.

In a third aspect, an electronic device is provided according to an embodiment of the present disclosure. The electronic device includes a bus, a transceiver, a memory, a processor, and a computer program stored on the memory and executable on the processor. The transceiver, the memory and the processor are connected to each other through the bus. The computer program, when executed by the processor, implements steps of the battery temperature monitoring point identification and abnormality detection method according to any one of the first aspect.

In a fourth aspect, a computer-readable storage medium, on which a computer program is stored, is provided according to an embodiment of the present disclosure. The computer program, when executed by a processor, implements steps of the battery temperature monitoring point identification and abnormality detection method according to any one of the first aspect.

In summary, in the battery temperature monitoring point identification and abnormality detection method according to the embodiments of the present disclosure, a second-order RC equivalent circuit model is established for a battery, and an optimal parameter of the battery is obtained by using the second-order RC equivalent circuit model, distances between temperature monitoring points in the battery module and the battery are obtained by using the optimal parameter, and effectiveness of the temperature monitoring points is determined by using the distance. In addition, the distances between the temperature monitoring points and the battery are determined by using an algorithm such as Kalman filtering and particle swarm, and the effectiveness and abnormality of the temperature monitoring points are determined again by observing the distribution of the distances. Compared with the solution in the conventional technology that requires to disassemble the battery module to determine the effectiveness of the temperature monitoring points, in a case of a large number of battery modules that cannot be disassembled, the effectiveness and abnormality of the temperature monitoring points can be detected without disassembling the battery modules, such that whether the temperature monitoring point is shifted or disconnected can be determined in a time-saving and labor-saving manner, and the effectiveness of the temperature monitoring point can be rapidly determined.

### BRIEF DESCRIPTION OF THE DRAWINGS

The drawings to be used in the embodiments of the present disclosure or the background art are described below in order to more clearly illustrate the technical solutions in the embodiments of the present disclosure or the background art.

FIG. 1 shows a flow chart of a battery temperature monitoring point identification and abnormality detection method according to an embodiment of the present disclosure;

FIG. 2 shows a schematic diagram of a real temperature and a fitted temperature obtained by a model of a battery temperature monitoring point identification and abnormality detection method according to an embodiment of the present disclosure;

FIG. 3 shows a distribution diagram of the distances between the temperature monitoring points and the battery on two different dates of the battery temperature monitoring point identification and abnormality detection method according to an embodiment of the present disclosure;

FIG. 4 shows a schematic diagram of connection between modules of a battery temperature monitoring point identification and abnormality detection apparatus according to an embodiment of the present disclosure; and

FIG. 5 shows a schematic structural diagram of an electronic device for a battery temperature monitoring point identification and abnormality detection method according to an embodiment of the present disclosure.

### DETAILED DESCRIPTION

Technical solutions of embodiments of the present disclosure are clearly and completely described hereinafter in conjunction with the drawings of the embodiments of the present disclosure. Apparently, the embodiments described in the following are only some embodiments of the present disclosure, rather than all embodiments. Any other embodiments obtained by those skilled in the art based on the embodiments in the present disclosure without any creative work fall in the scope of protection of the present disclosure. In order to provide those skilled in the art with a better understanding of the technical solutions of the present disclosure, the present disclosure is described in further detail below in conjunction with the accompanying drawings and specific embodiments.

The battery module is the smallest component of energy storage power station equipment. The battery module includes batteries and temperature monitoring points. Temperature is an important factor affecting battery safety and performance. Battery aging is accelerated at an excessive high or low temperature. By observing the change in battery temperature, thermal abuse of the battery can be prevented to a certain extent and thermal runaway of the battery can be monitored. The effectiveness of the battery temperature monitoring point (or referred to as temperature monitoring point) is the basis for monitoring the temperature of the battery. Abnormal or failed temperature monitoring point accelerates the aging of the battery in slight cases, and may cause a thermal safety accident of the battery in serious cases. During the use of the battery module, the temperature monitoring point may be sifted and floated, resulting in poor effectiveness or failure of the temperature monitoring point. In order to effectively determine the effectiveness and abnormality of the temperature monitoring point in the battery module, a battery temperature monitoring point identification and abnormality detection method and apparatus, and an electronic device are provided according to the present disclosure, which can identify the distance between the temperature monitoring point and the battery, and determine the effectiveness and abnormality of the temperature monitoring point by observing the distribution of distances between all temperature monitoring points and the battery in the entire battery module.

### First Embodiment

A battery temperature monitoring point identification and abnormality detection method according to this embodiment is executed by a server.

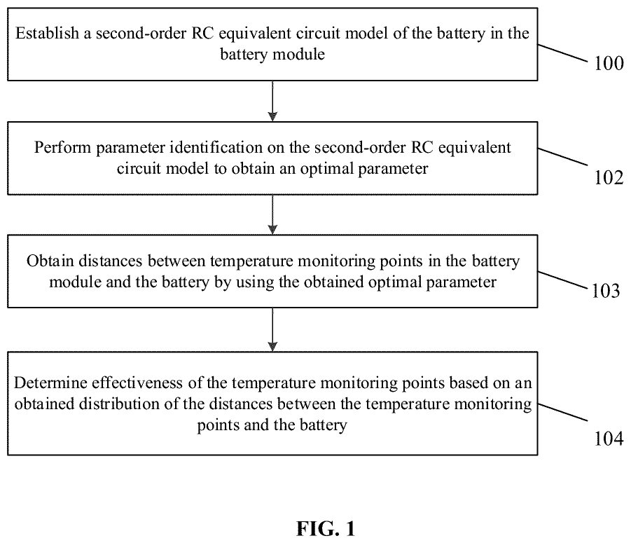

A battery temperature monitoring point identification and abnormality detection method is provided according to this embodiment. Reference is made to FIG. 1, which shows a flow chart of a battery temperature monitoring point identification and abnormality detection method. The method is applied to a battery module, where a temperature sensor inside the battery module is determined as a temperature monitoring point of a battery, and the method includes the following steps S100 to S103.

In step S100, a second-order RC equivalent circuit model of the battery in the battery module is established.

In the above step 100, common equivalent circuit models include a first-order RC network, a second-order RC network and an n-order RC network. Generally, the first-order RC network model has a great error, the accuracy of the second-order and higher order RC network models is improved as compared with the first-order RC network. However, the higher order of the RC network does not necessarily correspond to higher accuracy. When the order exceeds five, the error of the RC network equivalent circuit model is increased, and the computational complexity is further increased. The RC equivalent circuit model of the battery is established in the above step 100 to accurately obtain the relevant parameters of the battery. Therefore, considering the accuracy in combination with computational complexity, the second-order RC equivalent circuit model is preferred to model the battery.

The specific process of establishing the second-order RC equivalent circuit model of the battery in the battery module is an existing technology and will not be described in detail herein.

In step 101, parameter identification is performed on the second-order RC equivalent circuit model to obtain an optimal parameter.

In the above step 101, the performing parameter identification on the second-order RC equivalent circuit model to obtain an optimal parameter may include the following steps (1) to (5).

(1) Optimal parameter identification is performed on the second-order RC equivalent circuit model by using a Kalman filter algorithm to identify a function parameter in a charging and discharging process of the battery. The function parameter includes: an open circuit voltage OCV, a resistance and other parameters. The other parameters include: an electrochemical polarization capacitance of the battery, a concentration polarization capacitance of the battery and a constant coefficient to be fitted.

The resistance includes: an ohmic internal resistance of the battery, an electrochemical polarization internal resistance of the battery and a concentration polarization internal resistance of the battery.

After the parameter in the above step (1) is obtained, the second-order RC equivalent circuit is established, which satisfies:

$$\\ U = OCV - I * {R}_{0} - I * {R}_{1} ( 1 - {e}^{{}_{} - \frac{Δ t}{{R}_{1} * {C}_{1}}} ) - I * {R}_{2} ( 1 - {e}^{{}_{} - \frac{Δ t}{{R}_{2} * {C}_{2}}} ) ,$$

where U is a voltage of the battery, OCV is the open circuit voltage of the battery, I is a current of the battery, R₀ is the ohmic internal resistance of the battery, R₁ is the electrochemical polarization internal resistance of the battery, R₂ is the concentration polarization internal resistance of the battery, C₁ is an electrochemical polarization capacitance of the battery, C₂ is a concentration polarization capacitance of the battery, Δt is charging and discharging time of the battery;

The ohmic internal resistance, the electrochemical polarization internal resistance, and the concentration polarization capacitance of the equivalent circuit in the above step (1) are introduced as follows.

The battery achieves current output through intercalation, deintercalation and movement of ions between the positive and negative electrodes. Correspondingly, during the process of electrochemical reaction and ion movement, a certain resistance is generated and is simulated by using an internal resistance when modeling. Depending on different formation mechanism of the internal resistance when the battery is working, the internal resistance of the battery may be further classified into an ohmic internal resistance and a polarization internal resistance. The ohmic internal resistance is caused by the resistance encountered by ions during movement. Polarization internal resistance is caused by properties of the material, and may be further classified into an electrochemical polarization internal resistance and a concentration polarization internal resistance. The electrochemical polarization may also be referred to as activation polarization, and is caused by the electrochemical reaction rate of the positive and negative active materials being smaller than the electron movement rate.

(2) A battery charging state of the battery in the battery module is obtained, and a relational expression between the open circuit voltage OCV and the battery charging state is established, where the relational expression between the open circuit voltage OCV and the battery charging state is:

$$\\ f ( SOC ) = a * {SOC}^{{}_{} 7} + b * {SOC}^{{}_{} 6} + c * {SOC}^{{}_{} 5} + d * {SOC}^{{}_{} 4} + e * {SOC}^{{}_{} 3} + f * {SOC}^{{}_{} 2} + g * {SOC}^{{}_{} 1} + h ,$$

where each of a, b, . . . , h is a constant coefficient to be fitted, f(SOC) is an identified open circuit voltage OCV during the charging and discharging process of the battery, and SOC is the battery charging state.

The power of the battery charging state in the above relational expression may be low-order or high-order, but during an actual test process, the optimal effect is achieved when the power is preferably 7. Further, the above relational expression of the open circuit voltage OCV may alternatively be expressed by another functional relational expression, as long as the open circuit voltage OCV and the battery charging state can be accurately described.

(3) The relational expression between the open circuit voltage OCV and the battery charging state is fitted by using a least square method to obtain a fitting value of the function parameter.

(4) A value range of the function parameter is determined based on the obtained fitting value of the function parameter.

(5) A secondary identification of the function parameter is performed based on the relational expression between the open circuit voltage OCV and the battery charging state and the determined value range of the function parameter, to obtain the optimal parameter of the function parameter.

Further, the performing a secondary identification of the function parameter based on the relational expression between the open circuit voltage OCV and the battery charging state and the determined value range of the function parameter in the above step (5), to obtain the optimal parameter of the function parameter includes:

$$\\ U = OCV - I * {R}_{0} - I * {R}_{1} ( 1 - {e}^{{}_{} - \frac{Δ t}{{R}_{1} * {C}_{1}}} ) - I * {R}_{2} ( 1 - {e}^{{}_{} - \frac{Δ t}{{R}_{2} * {C}_{2}}} ) ,$$

where each of a, b, . . . , h is the constant coefficient to be fitted this time; R₀ is the ohmic internal resistance of the battery, R₁ is the electrochemical polarization internal resistance of the battery, R₂ is the concentration polarization internal resistance of the battery, C₁ is an electrochemical polarization capacitance of the battery, C₂ is a concentration polarization capacitance of the battery, Δt is charging and discharging time of the battery, OCV is the open circuit voltage; and I is a current of the battery.

The second-order RC equivalent circuit model and the relational expression between the open circuit voltage OCV and the battery charging state are processed within the value range of the function parameter by using a particle swarm algorithm, to perform the secondary identification of the function parameter, to obtain the optimal parameter of the function parameter.

In step 102, distances between temperature monitoring points in the battery module and the battery are obtained by using the obtained optimal parameter.

In the above step 102, the obtaining distances between multiple temperature monitoring points in the battery module and the battery by using the obtained optimal parameter includes following step:

establishing a lumped heat transfer equation of the battery by using the optimal parameter and obtaining the distances between the temperature monitoring points in the battery module and the battery by using the lumped heat transfer equation.

Correspondingly, the lumped heat transfer equation satisfies:

$$\\ ρ * {C}_{p} * \frac{dT}{dt} = \frac{{Q}_{total}}{V} + \frac{A * h * ( {T}_{amb} - T )}{V} + {\sum }_{i}^{n} λ \frac{( {T}_{i} - T )}{{dist}_{i}^{{}_{} 2}} ,$$

where ρ is an equivalent density of the battery, Cₚ is a specific heat capacity of the battery, dT is a temperature difference, dt is a time difference between two time instants, Qₜₒₜₐₗ is a total heat generation of the battery, A is a surface area of the battery, h is a convection heat transfer coefficient, T_{amb} is an ambient temperature, T is a temperature of the battery, n is a quantity of the temperature monitoring points, λ is a thermal conductivity, Tᵢ is a temperature value measured by an i-th temperature monitoring point, distᵢ is a distance from the battery to the i-th temperature monitoring point. The parameter to be identified in the above lumped heat transfer equation includes: the distance distᵢ from the battery to the i-th temperature monitoring point, the convection heat transfer coefficient h, and the temperature entropy coefficient

$$\\ \frac{\partial E}{\partial T} .$$

The distances distᵢ between the temperature monitoring points and the battery may be obtained by using the above lumped heat transfer equation.

Specifically, in the above step 102, in the lumped heat transfer equation, a total heat generated by the battery satisfies:

$$\\ {Q}_{total} = I * I * ( {R}_{0} + {R}_{1} + {R}_{2} ) + I * T * \frac{\partial E}{\partial T} ,$$

where I is the current of the battery, R₀ is the ohmic internal resistance of the battery, R₁ is the electrochemical polarization internal resistance of the battery, R₂ is the concentration polarization internal resistance of the battery, T is the temperature of the battery, and

$$\frac{\partial E}{\partial T}$$

is the temperature entropy coefficient.

In step 103, effectiveness of the temperature monitoring points is obtained based on an obtained distribution of the distances between the temperature monitoring points and the battery.

In the above step 103, by identifying battery charging and discharging data at different time instants, the distribution of temperature monitoring point distances on different dates is obtained.

If the distribution of the temperature monitoring point distances on different dates has an abnormal outlier or has an increased distribution range, it may be determined that a temperature monitoring point is abnormal or the effectiveness of the temperature monitoring point gradually deteriorates. Referring to the distribution diagram of the distances between the temperature monitoring points and the battery on two different dates shown in FIG. 3, it can be seen from observation that the temperature monitoring points of the battery module have high effectiveness and include no abnormal point. The above-mentioned abnormal outlier may be defined as follows. Given that the distribution of the result load of the first identification is denoted as p, that is, the distances dist between all identified temperature monitoring points and the battery follows the distribution p, which is expressed as dist ˜p(a), where a represents a coefficient of the distribution. Further, the horizontal axis in FIG. 3 represents the distance between the identified temperature monitoring point and the battery, and the vertical axis represents the frequency. FIG. 3 shows the distribution diagram of the identified distances, that is, the distribution diagram of the identification results on different dates. It can be seen from the FIG. 3 that the two distributions are similar, and it may be determined that the temperature monitoring points of the battery module on the two dates have not normality.

If a next identification result shows that there is a temperature monitoring point from which the distance to the battery does not conform to the distribution, or the distance between the temperature monitoring point and the battery exceeds the threshold range of the distribution, the temperature monitoring point is determined to be abnormal.

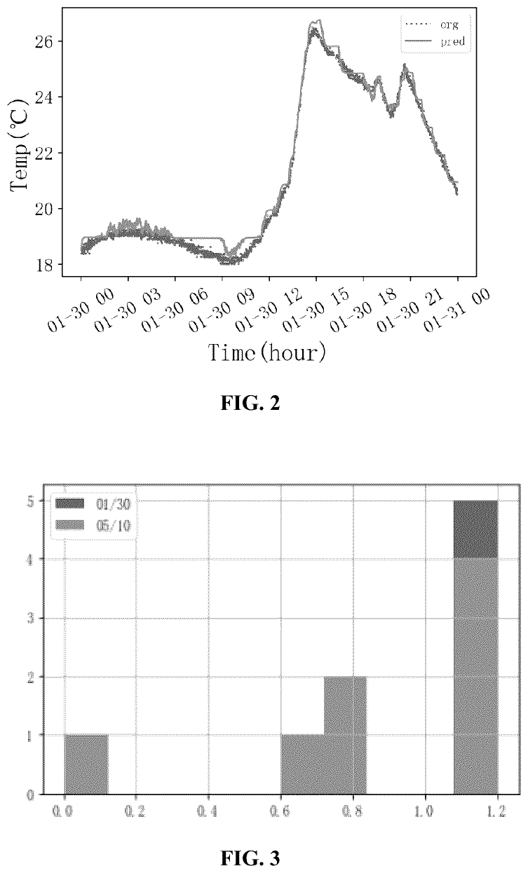

Further, in step 103, an electrical parameter is obtained based on the lumped heat transfer equation and the optimal parameter. A thermal parameter is identified by using the particle swarm algorithm and is brought into the lumped heat transfer equation for fitting. Referring to FIG. 2, which shows a schematic diagram of a real temperature and the fitted temperature obtained by the model, the real temperature and the fitted temperature situation obtained by the lumped heat transfer equation are obtained.

In summary, in the battery temperature monitoring point identification and abnormality detection method according to the embodiments of the present disclosure, a second-order RC equivalent circuit model is established for a battery, and an optimal parameter of the battery is obtained by using the second-order RC equivalent circuit model, distances between temperature monitoring points in the battery module and the battery are obtained by using the optimal parameter, and effectiveness of the temperature monitoring points are determined by using the distances. In addition, the distances between the temperature monitoring points and the battery are determined by using an algorithm such as Kalman filtering and particle swarm, and the effectiveness and abnormality of the temperature monitoring points are determined again by observing the distribution of the distance. Compared with the solution in the conventional technology that requires to disassemble the battery module to determine the effectiveness of the temperature monitoring points, in a case of a large number of battery modules that cannot be disassembled, the effectiveness and abnormality of the temperature monitoring points can be detected without disassembling the battery modules, such that whether the temperature monitoring point is shifted or disconnected can be determined in a time-saving and labor-saving manner, and the effectiveness of the temperature monitoring point can be rapidly determined.

### Second Embodiment

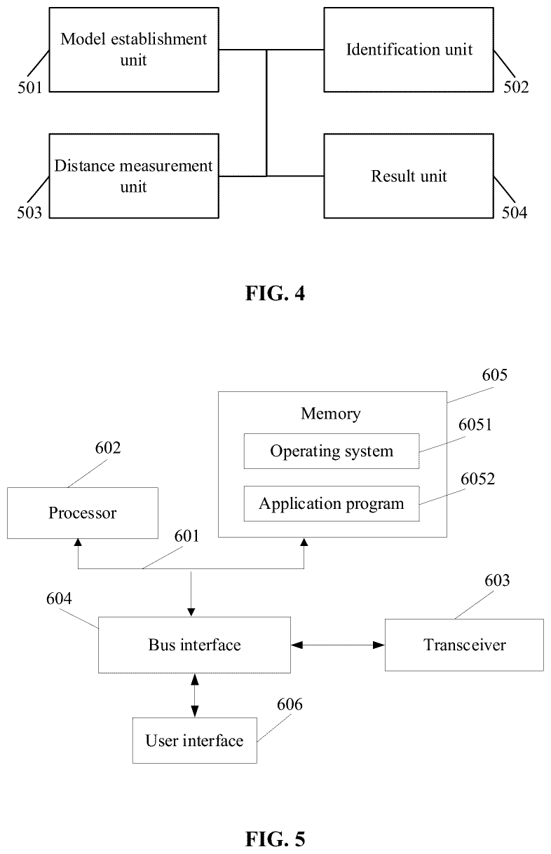

Referring to FIG. 4, which shows a schematic diagram of connection between modules of a battery temperature monitoring point identification and abnormality detection apparatus, a battery temperature monitoring point identification and abnormality detection apparatus is provided according to this embodiment, which includes a model establishment unit 501, an identification unit 502, a distance measurement unit 503, and a result unit 504.

The model establishment unit 501 is configured to establish a second-order RC equivalent circuit model of a battery in a battery module.

The identification unit 502 is configured to perform parameter identification on the second-order RC equivalent circuit model to obtain an optimal parameter.

The distance measurement unit 503 is configured to obtain distances between temperature monitoring points in the battery module and the battery by using the obtained optimal parameter.

The result unit 504 is configured to determine effectiveness of the temperature monitoring points based on an obtained distribution of the distances between the temperature monitoring points and the battery.

In an embodiment, the identification unit 502 includes a parameter unit, an expression establishment unit, a fitting unit, and a determination unit.

The parameter unit is configured to perform optimal parameter identification on the second-order RC equivalent circuit model by using a Kalman filter algorithm to identify the function parameter in the charging and discharging process of the battery, where the function parameter includes: an open circuit voltage OCV, a resistance and other parameters. The other parameters include a constant coefficient to be fitted.

The second-order RC equivalent circuit in the model establishment unit 501 satisfies:

$$U = OC V - I * {R}_{0} - I * {R}_{1} ( 1 - {e}^{- \frac{Δ t}{{R}_{1} * {C}_{1}}} ) - I * {R}_{2} ( 1 - {e}^{- \frac{Δ t}{{R}_{2} * {C}_{2}}} ) ,$$

where U is a voltage of the battery, OCV is the open circuit voltage of the battery, I is a current of the battery, R₀ is the ohmic internal resistance of the battery, R₁ is the electrochemical polarization internal resistance of the battery, R₂ is the concentration polarization internal resistance of the battery, C₁ is an electrochemical polarization capacitance of the battery, C₂ is a concentration polarization capacitance of the battery, and Δt is a time difference between a charging process of the battery and a discharging process of the battery.

The expression establishment unit is configured to obtain a battery charging state in the battery module, and establish a relational expression between the open circuit voltage OCV and the battery charging state, where the relational expression between the open circuit voltage OCV and the battery charging state is:

$$f ( SOC ) = a * {SOC}^{7} + b * {SOC}^{6} + c * {SOC}^{5} + d * {SOC}^{4} + e * {SOC}^{3} + f * {SOC}^{2} + g * {SOC}^{1} + h ;$$

where each of a, b, . . . , h is a function parameter to be fitted, f(SOC) is an identified open circuit voltage OCV during the charging and discharging process of the battery, and SOC is the battery charging state.

The fitting unit is configured to fit the relational expression between the open circuit voltage OCV and the battery charging state by using a least square method to obtain a fitting value of the function parameter.

The determination unit is configured to process the second-order RC equivalent circuit model and the relational expression between the open circuit voltage OCV and the battery charging state within the value range of the function parameter by using a particle swarm algorithm, to perform a secondary identification of the function parameter, to obtain the optimal parameter of the function parameter.

The second-order RC equivalent circuit model mentioned in the determination unit satisfies:

$$U = OC V - I * {R}_{0} - I * {R}_{1} ( 1 - {e}^{- \frac{Δ t}{{R}_{1} * {C}_{1}}} ) - I * {R}_{2} ( 1 - {e}^{- \frac{Δ t}{{R}_{2} * {C}_{2}}} ) ,$$

where each of a, b, . . . , h is the constant coefficient to be fitted this time; R₀ is the ohmic internal resistance of the battery, I is the current of the battery, R₁ is the electrochemical polarization internal resistance of the battery, R₂ is the concentration polarization internal resistance of the battery, C₁ is the electrochemical polarization capacitance of the battery, and C₂ is the concentration polarization capacitance of the battery.

In an embodiment, the distance measurement unit 503 obtaining distances between temperature monitoring points in the battery module and the battery by using the obtained optimal parameter includes:

establishing a lumped heat transfer equation of the battery by using the optimal parameter and obtaining the distances between the temperature monitoring points in the battery module and the battery by using the established lumped heat transfer equation.

The lumped heat transfer equation is expressed as:

$$ρ * {C}_{p} * \frac{dT}{dt} = \frac{{Q}_{total}}{V} + \frac{A * h * ( {T}_{amb} - T )}{V} + {\sum }_{i}^{n} λ \frac{( {T}_{i} - T )}{{dist}_{i}^{2}} ,$$

where ρ is an equivalent density of the battery, Cₚ is a specific heat capacity of the battery, dT is a temperature difference, dt is a time difference between two time instants, Qₜₒₜₐₗ is a total heat generation of the battery, A is a surface area of the battery, h is a convection heat transfer coefficient, T_{amb} is an ambient temperature, T is a temperature of the battery, n is a quantity of the temperature monitoring points, λ is a thermal conductivity, Tᵢ is a temperature value measured by an i-th temperature monitoring point, distᵢ is a distance from the battery to the i-th temperature monitoring point.

The total heat generated by the battery in the lumped heat transfer equation satisfies:

$${Q}_{total} = I * I * ( {R}_{0} + {R}_{1} + {R}_{2} ) + I * T * \frac{\partial E}{\partial T} ,$$

where I is the current of the battery, R₀ is the ohmic internal resistance of the battery, R₁ is the electrochemical polarization internal resistance of the battery, R₂ is the concentration polarization internal resistance of the battery, T is the temperature of the battery, and ∂E/∂T is the temperature entropy coefficient.

In summary, in the battery temperature monitoring point identification and abnormality detection apparatus according to this embodiment, a second-order RC equivalent circuit model is established for the battery through a model establishment unit, and parameters in the model establishment unit are identified through an identification unit, to obtain an optimal parameter, a lumped heat transfer equation is established through a test unit, distances between temperature monitoring points and the battery are determined by using the lumped heat transfer equation, and effectiveness and anomality of the temperature monitoring points are detected again by observing a distribution of the distances. Compared with the solution in the conventional technology that requires to disassemble the battery module, in a case of a large number of battery modules that cannot be disassembled, whether the temperature monitoring point is shifted or disconnected can be determined in a time-saving and labor-saving manner, and the effectiveness of the temperature monitoring point can be rapidly determined.

### Third Embodiment

Referring to FIG. 5, which shows a schematic structural diagram of an electronic device for a battery temperature monitoring point identification and abnormality detection method, an electronic device is further provided according to this embodiment. The electronic device includes a bus 601, a processor 602, a transceiver 603, a bus interface 604, a memory 605, and a user interface 606.

In this embodiment, the electronic device further includes a computer program stored in the memory 605 and executable on the processor 602. The computer program, when executed by the processor 602, implements processes of the battery temperature monitoring point identification and abnormality detection method in the above embodiment.

The transceiver 603 is configured to receive and transmit data under control of the processor 602.

In this embodiment, a bus structure (represented by the bus 601) includes any number of interconnected buses and bridges. The bus 601 connects various circuits including one or more processors represented by the processor 602 and a memory represented by the memory 605 together.

The bus 601 represents one or more of any one of several types of bus structures, including a memory bus and a memory controller, a peripheral bus, an accelerated graphic port (AGP), a processor or a local bus using any bus structure among various bus architectures. For illustration rather than limitation, such architectures include: an industry standard architecture (ISA) bus, a micro channel architecture (MCA) bus, an extended ISA (EISA) bus, a video electronics standard association (VESA) bus, and a peripheral component interconnect (PCI) bus.

The processor 602 may be an integrated circuit chip with signal processing capabilities. In implementation, each step of the foregoing method embodiment may be completed by an integrated logic circuit of hardware or instructions in the form of software in the processor. The processor includes: a general-purpose processor, a central processing unit (CPU), a network processor (NP), a digital signal processor (DSP), an application specific integrated circuit (ASIC), a field programmable gate array (FPGA), a complex programmable logic device (CPLD), a programmable logic array (PLA), a microcontroller unit (MCU) or other programmable logic device, a discrete gate, a transistor logic device, a discrete hardware component. The methods, steps, and logical block diagrams disclosed in this embodiment may be implemented or performed. For example, the processor may be a single-core processor or a multi-core processor, and the processor may be integrated on a single chip or located on various chips.

The processor 602 may be a microprocessor or any conventional processor. The steps of the method disclosed in this embodiment may be directly performed and completed by a hardware decoding processor, or may be performed and completed by a combination of hardware and software modules in the decoding processor. The software module may be located in a readable storage medium known in the art such as a random-access memory (RAM), a flash memory, a read-only memory (ROM), a programmable read-only memory (PROM), an erasable programmable read-only memory (EPROM), and a register. The readable storage medium is located in the memory. The processor reads the information in the memory and completes the steps of the above method in combination with its hardware.

The bus 601 further connects various other circuits such as a peripheral device, a voltage regulator, or a power management circuit, and the bus interface 604 provides an interface between the bus 601 and the transceiver 603, which are well known in the art. Therefore, the bus 601 and the bus interface 604 are not further described in this embodiment.

The transceiver 603 may include one element or multiple elements, e.g., multiple receivers and transmitters, and provide a unit for communicating with various other devices on a transmission medium. For example, the transceiver 603 receives external data from other devices, and sends the data processed by the processor 602 to other devices. Depending on the nature of the computer system, a user interface 606 may also be provided, including a touch screen, a physical keyboard, a display, a mouse, a speaker, a microphone, a trackball, a joystick, and a stylus.

It should be understood that, in this embodiment, the memory 605 may further include a memory remotely set with respect to the processor 602. The remotely set memory may be connected to the server through a network. One or more parts of the above-mentioned network may be an ad hoc network, an intranet, an extranet, a virtual private network (VPN), a local area network (LAN), a wireless local area network (WLAN), a wide area network (WAN), a wireless wide area network (WWAN), a metropolitan area network (MAN), the Internet (Internet), a public switched telephone network (PSTN), an plain old telephone service network (POTS), a cellular telephone network, a wireless network, a wireless fidelity (Wi-Fi) network and a combination of two or more of the aforementioned networks. For example, the cellular telephone network and the wireless network may be a global mobile communications (GSM) system, a code division multiple access (CDMA) system, a global interconnection for microwave access (WiMAX) system, a general packet radio service (GPRS) system, a broadband code division multiple access (WCDMA) system, a long-term evolution (LTE) system, an LTE frequency division duplex (FDD) system, an LTE time division duplex (TDD) system, an advanced long term evolution (LTE-A) system, a universal mobile telecommunications (UMTS) system, an enhanced mobile broadband (cMBB) system, a massive machine type of communication (mMTC) system, a ultra-reliable low latency communications (uRLLC) system and the like.

It should be understood that the memory 605 in this embodiment may be a volatile memory or a non-volatile memory, or may include both a volatile memory and a non-volatile memory. The non-volatile memory includes: a read-only memory (ROM), a programmable read-only memory (PROM), an erasable programmable read-only memory (EPROM), an electrically erasable programmable read-only memory (EEPROM) or a flash memory.

The volatile memory includes: a random-access memory (RAM), which serves as an external cache. For illustration rather than limitation, various RAMs are available, such as: a static random-access memory (SRAM), a dynamic random-access memory (DRAM), a synchronous dynamic random-access memory (SDRAM), a double data rate synchronous dynamic random-access memory (DDRSDRAM), an enhanced synchronous dynamic random-access memory (ESDRAM), a synchronous link dynamic random-access memory (SLDRAM) and a direct Rambus random access memory (DRRAM). The memory 605 of the electronic device described in this embodiment includes but is not limited to the above and any other types of memory.

In this embodiment, the memory 605 stores the following elements of an operating system 6051 and an application program 6052: executable modules, data structures, or a subset thereof, or an extension set thereof.

Specifically, the operating system 6051 includes various system programs, such as a framework layer, a core library layer, a driver layer and the like, for implementing various basic services and processing hardware-based tasks. The application program 6052 includes various application programs 6052, such as a media player and a browser, for implementing various application services. A program that implements the method of this embodiment may be included in the application program 6052. The application program 6052 includes: an applet, an object, a component, logic, a data structure, and other computer system executable instructions that perform specific tasks or implement specific abstract data types.

### Fourth Embodiment

In addition, a computer-readable storage medium on which a computer program is stored is further provided according to this embodiment. When the computer program is executed by the processor, steps of the battery temperature monitoring point identification and abnormality detection method according to the above embodiment are implemented, and the same technical effects can be achieved. In order to avoid repetition, details are not repeated here.

The computer-readable storage medium includes permanent and non-permanent, removable and non-removable media, and is a tangible device that retains and stores instructions executed by an instruction execution device. The computer-readable storage medium includes: an electronic storage device, a magnetic storage device, an optical storage device, an electromagnetic storage device, a semiconductor storage device, and any suitable combination of the foregoing. The computer-readable storage medium includes: a phase change memory (PRAM), a static random access memory (SRAM), a dynamic random access memory (DRAM), other types of random access memory (RAM), a read-only memory (ROM), a non-volatile random access memory (NVRAM), an electrically erasable programmable read-only memory (EEPROM), a flash memory or other memories, a compact disc read-only memory (CD-ROM), a digital versatile disc (DVD) or other optical storage device, a magnetic cassette memory, a magnetic tape disk memory or other magnetic storage devices, a memory stick, a mechanical encoding device (such as a punched card or raised structure in a groove on which instructions are recorded) or any other non-transmission medium, and is configured to store information that can be accessed by a computing device. According to the definition in this embodiment, the computer-readable storage medium does not include temporary signals, such as radio waves or other freely transmitted electromagnetic waves, electromagnetic waves transmitted through waveguides or other transmission media (e.g., a light pulse passing through an optical fiber cable) or electrical signals transmitted through wires.

In the embodiments of the present disclosure, it should be understood that the disclosed apparatus, electronic device, and method may be implemented in other ways. For example, the apparatus embodiments described above are only illustrative. For example, the division of the modules or units is only a logical function division, and there may be other division manners in actual implementation. For example, multiple units or components may be combined or integrated into another system, or some features may be omitted or not implemented. In addition, the shown or discussed mutual coupling or direct coupling or communication connection may be indirect coupling or communication connection through some interfaces, devices or units, and may also be electrical, mechanical or other forms of connection.

The units described as separate components may or may not be physically separate. Components shown as units may or may not be a physical unit, that is, may be located in one position or distributed on multiple network units. Some or all of the units may be selected according to actual needs to solve the problems to be solved by the solutions of this embodiment.

In addition, the functional units in the various embodiments may be integrated into one processing unit, or the units may separate physically, or two or more units may be integrated into one unit. The above-mentioned integrated unit may be implemented in the form of hardware or software functional unit.

If the integrated unit is implemented in the form of a software functional unit and sold or used as an independent product, the integrated unit may be stored in a computer-readable storage medium. Based on this understanding, the technical solutions of this embodiment are essentially or a part that contributes to the conventional technology, or all or part of the technical solutions may be embodied in the form of a computer software product. The computer software product is stored in a storage medium and includes a number of instructions so that a computer device (such as a personal computer, a server, a data center or other network devices) execute all or part of the steps of the method described in the embodiments. The aforementioned storage medium includes various media capable of storing program codes as listed above.

In the description of this embodiment, those skilled in the art should understand that this embodiment may be implemented as a method, an apparatus, an electronic device, and a computer-readable storage medium. Therefore, this embodiment may be specifically implemented in the following forms: complete hardware, complete software (including firmware, resident software, microcode and the like), and a combination of hardware and software. In addition, in some embodiments, this embodiment may also be implemented in the form of a computer program product in one or more computer-readable storage media, and the computer-readable storage medium includes computer program codes.

The aforementioned computer-readable storage medium may adopt any combination of one or more computer-readable storage media. The computer-readable storage medium includes: an electrical, magnetic, optical, electromagnetic, infrared, or semiconductor system, apparatus, or device, or any combination of the above. More specific examples of computer-readable storage media include: a portable computer disk, a hard disk, a random-access memory (RAM), a read-only memory (ROM), an erasable programmable read-only memory (EPROM), a flash memory, an optical fiber, a compact disc read-only memory (CD-ROM), an optical storage device, a magnetic storage device or any combination of the above. In this embodiment, the computer-readable storage medium may be any tangible medium that includes or stores a program, and the program may be executed by an instruction execution system, apparatus, or device, or in combination therewith.

The computer program code included in the above-mentioned computer-readable storage medium may be transmitted by any suitable medium, including: a wireless medium, a wired medium, an optical cable, radio frequency (RF), or any suitable combination of the above.

The computer program codes for implementing the operations in this embodiment may be written in the form of assembly instructions, instruction set architecture (ISA) instructions, machine instructions, machine-related instructions, microcode, firmware instructions, state setting data, integrated circuit configuration data, or in one or more programming languages or a combination thereof. The programming language includes object-oriented programming languages, such as Java, Smalltalk, and C++, as well as conventional procedural programming languages, such as C language or similar programming languages. The computer program codes may be executed entirely on the user computer, partly on the user computer, executed as an independent software package, partly on the user computer and partly on a remote computer, and completely executed on a remote computer or server. In the case of a remote computer, the remote computer can be connected to a user computer or an external computer through any kind of network, including: a local area network (LAN) or a wide area network (WAN).

This embodiment describes the provided method, apparatus, and the electronic device through flowcharts and/or block diagrams.

It should be understood that each block in the flowcharts and/or block diagrams and the combination of blocks in the flowcharts and/or block diagrams may be implemented by computer readable program instructions. These computer-readable program instructions may be provided to the processor of a general-purpose computer, a special-purpose computer, or other programmable data processing device, to produce a machine. These computer-readable program instructions are executed by a computer or other programmable data processing device to generate a device that implements the functions/operations specified by the blocks in the flowcharts and/or block diagrams.

These computer-readable program instructions may also be stored in a computer-readable storage medium that can operate a computer or other programmable data processing device in a specific manner. In this way, the instructions stored in the computer-readable storage medium produce an instruction device product that includes the functions/operations specified in the blocks in the flowcharts and/or block diagrams.

Alternatively, the computer-readable program instructions are loaded onto a computer, other programmable data processing device, or other device, so that a series of operation steps are executed on the computer, other programmable data processing device, or other device to produce a computer-implemented process, so that the instructions executed on the computer or other programmable data processing device can provide a process for implementing the functions/operations specified by the blocks in the flowcharts and/or block diagrams.

Specific implementations of the embodiments of the present disclosure are described above, and the scope of protection of the embodiments of the present disclosure is not limited thereto. Any person skilled in the art can easily conceive of changes or substitutions within the technical scope disclosed in the embodiments of the present disclosure, and these changes or substitutions should be covered by the scope of protection of the embodiments of the present disclosure. Therefore, the scope of protection of the embodiments of the present disclosure should be subject to the protection scope of the claims.

1. A battery temperature monitoring point identification and abnormality detection method, wherein the method is applied to a battery module, a temperature sensor inside the battery module is determined as a temperature monitoring point of a battery, and the method comprises:
establishing a second-order RC equivalent circuit model of the battery in the battery module;
performing parameter identification on the second-order RC equivalent circuit model to obtain an optimal parameter; performing optimal parameter identification on the second-order RC equivalent circuit model by using a Kalman filter algorithm to identify a function parameter in a charging and discharging process of the battery;
obtaining distances between a plurality of temperature monitoring points in the battery module and the battery by using the obtained optimal parameter; establishing a lumped heat transfer equation of the battery by using the optimal parameter of the function parameter, and establishing a lumped heat transfer equation by using the optimal parameter and obtaining the distances between the temperature monitoring points in the battery module and the battery, wherein
the lumped heat transfer equation is expressed as:
$$ρ * {C}_{p} * \frac{dT}{dt} = \frac{{Q}_{total}}{V} + \frac{A * h * ( {T}_{amb} - T )}{V} + {\sum }_{i}^{n} λ \frac{( {T}_{i} - T )}{{dist}_{i}^{2}} ,$$
wherein ρ is an equivalent density of the battery, Cₚ is a specific heat capacity of the battery, dT is a temperature difference at a previous time instant, dt is a time difference between two time instants, Qₜₒₜₐₗ is a total heat generation of the battery, A is a surface area of the battery, h is a convection heat transfer coefficient, T_{amb} is an ambient temperature, T is a temperature of the battery, n is a quantity of the temperature monitoring points, λ is a thermal conductivity, Tᵢ is a temperature value measured by an i-th temperature monitoring point, distᵢ is a distance from the battery to the i-th temperature monitoring point; and
determining effectiveness of the temperature monitoring points based on an obtained distribution of the distances between the temperature monitoring points and the battery.

2. The battery temperature monitoring point identification and abnormality detection method according to claim 1, wherein the performing parameter identification on the second-order RC equivalent circuit model to obtain an optimal parameter comprises:
performing optimal parameter identification on the second-order RC equivalent circuit model by using a Kalman filter algorithm to identify the function parameter in the charging and discharging process of the battery, wherein the function parameter comprises: an open circuit voltage OCV, a resistance and other parameters; the other parameters comprise: an electrochemical polarization capacitance of the battery, a concentration polarization capacitance of the battery and a constant coefficient to be fitted; the resistance comprises: an ohmic internal resistance of the battery, an electrochemical polarization internal resistance of the battery and a concentration polarization internal resistance of the battery, wherein
the second-order RC equivalent circuit satisfies:
$$U = OC V - I * {R}_{0} - I * {R}_{1} ( 1 - {e}^{- \frac{Δ t}{{R}_{1} * {C}_{1}}} ) - I * {R}_{2} ( 1 - {e}^{- \frac{Δ t}{{R}_{2} * {C}_{2}}} ) ,$$
wherein U is a voltage of the battery, OCV is the open circuit voltage of the battery, I is a current of the battery, R₀ is the ohmic internal resistance of the battery, R₁ is the electrochemical polarization internal resistance of the battery, R₂ is the concentration polarization internal resistance of the battery, C₁ is an electrochemical polarization capacitance of the battery, C₂ is a concentration polarization capacitance of the battery, and Δt is a time difference between a charging process of the battery and a discharging process of the battery;
obtaining a battery charging state of the battery in the battery module, and establishing a relational expression between the open circuit voltage OCV and the battery charging state, wherein the relational expression between the open circuit voltage OCV and the battery charging state is:
$$f ( SOC ) = a * {SOC}^{7} + b * {SOC}^{6} + c * {SOC}^{5} + d * {SOC}^{4} + e * {SOC}^{3} + f * {SOC}^{2} + g * {SOC}^{1} + h ;$$
wherein each of a, b, . . . , h is a constant coefficient to be fitted, f(SOC) is an identified open circuit voltage OCV during the charging and discharging process of the battery, and SOC is the battery charging state;
fitting the relational expression between the open circuit voltage OCV and the battery charging state by using a least square method to obtain a fitting value of the function parameter;
determining a value range of the function parameter based on the obtained fitting value of the function parameter; and
performing a secondary identification of the function parameter based on the relational expression between the open circuit voltage OCV and the battery charging state and the determined value range of the function parameter, to obtain the optimal parameter of the function parameter.

3. The battery temperature monitoring point identification and abnormality detection method according to claim 2, wherein the performing a secondary identification of the function parameter based on the relational expression between the open circuit voltage OCV and the battery charging state and the determined value range of the function parameter, to obtain the optimal parameter of the function parameter comprises:
processing the second-order RC equivalent circuit model and the relational expression between the open circuit voltage OCV and the battery charging state within the value range of the function parameter by using a particle swarm algorithm, to perform the secondary identification of the function parameter, to obtain the optimal parameter of the function parameter.

4. The battery temperature monitoring point identification and abnormality detection method according to claim 1, wherein the obtaining distances between a plurality of temperature monitoring points in the battery module and the battery by using the obtained optimal parameter comprises:
a total heat generated by the battery in the lumped heat transfer equation satisfies:
$${Q}_{total} = I * I * ( {R}_{0} + {R}_{1} + {R}_{2} ) + I * T * \frac{\partial E}{\partial T} ,$$
wherein I is a current of the battery, R₀ is an ohmic internal resistance of the battery, R₁ is an electrochemical polarization internal resistance of the battery, R₂ is a concentration polarization internal resistance of the battery, T is a temperature of the battery, and ∂E/∂T is a temperature entropy coefficient.

5. A battery temperature monitoring point identification and abnormality detection apparatus, comprising:
a model establishment unit, configured to establish a second-order RC equivalent circuit model of a battery in a battery module;
an identification unit, configured to perform parameter identification on the second-order RC equivalent circuit model to obtain an optimal parameter; perform optimal parameter identification on the second-order RC equivalent circuit model by using a Kalman filter algorithm to identify a function parameter in a charging and discharging process of the battery;
a distance measurement unit, configured to obtain distances between temperature monitoring points in the battery module and the battery by using the obtained optimal parameter; establish a lumped heat transfer equation of the battery by using the optimal parameter of the function parameter, and establish a lumped heat transfer equation by using the optimal parameter and obtain the distances between the temperature monitoring points in the battery module and the battery, wherein
the lumped heat transfer equation is expressed as:
$$ρ * {C}_{p} * \frac{dT}{dt} = \frac{{Q}_{total}}{V} + \frac{A * h * ( {T}_{amb} - T )}{V} + {\sum }_{i}^{n} λ \frac{( {T}_{i} - T )}{{dist}_{i}^{2}} ,$$
wherein ρ is an equivalent density of the battery, Cₚ is a specific heat capacity of the battery, dT is a temperature difference at a previous time instant, dt is a time difference between two time instants, Qₜₒₜₐₗ is a total heat generation of the battery, A is a surface area of the battery, h is a convection heat transfer coefficient, T_{amb} is an ambient temperature, T is a temperature of the battery, n is a quantity of the temperature monitoring points, λ is a thermal conductivity, Tᵢ is a temperature value measured by an i-th temperature monitoring point, distᵢ is a distance from the battery to the i-th temperature monitoring point; and
a result unit, configured to determine effectiveness of the temperature monitoring points based on an obtained distribution of the distances between the temperature monitoring points and the battery.

6. The battery temperature monitoring point identification and abnormality detection apparatus according to claim 5, wherein the identification unit comprises:
a parameter unit, configured to perform optimal parameter identification on the second-order RC equivalent circuit model by using a Kalman filter algorithm to identify the function parameter in the charging and discharging process of the battery, wherein the function parameter comprises: an open circuit voltage OCV, a resistance and other parameters; the other parameters comprise: an electrochemical polarization capacitance of the battery, a concentration polarization capacitance of the battery and a constant coefficient to be fitted; the resistance comprises: an ohmic internal resistance of the battery, an electrochemical polarization internal resistance of the battery and a concentration polarization internal resistance of the battery, wherein
the second-order RC equivalent circuit satisfies:
$$U = OC V - I * {R}_{0} - I * {R}_{1} ( 1 - {e}^{- \frac{Δ t}{{R}_{1} * {C}_{1}}} ) - I * {R}_{2} ( 1 - {e}^{- \frac{Δ t}{{R}_{2} * {C}_{2}}} ) ,$$
wherein U is a voltage of the battery, OCV is the open circuit voltage of the battery, I is a current of the battery, R₀ is the ohmic internal resistance of the battery, R₁ is the electrochemical polarization internal resistance of the battery, R₂ is the concentration polarization internal resistance of the battery, C₁ is an electrochemical polarization capacitance of the battery, C₂ is a concentration polarization capacitance of the battery, and Δt is a time difference between a charging process of the battery and a discharging process of the battery;
an expression establishment unit, configured to obtain a battery charging state in the battery module, and establish a relational expression between the open circuit voltage OCV and the battery charging state, wherein the relational expression between the open circuit voltage OCV and the battery charging state is:
$$f ( SOC ) = a * {SOC}^{7} + b * {SOC}^{6} + c * {SOC}^{5} + d * {SOC}^{4} + e * {SOC}^{3} + f * {SOC}^{2} + g * {SOC}^{1} + h ;$$
wherein each of a, b, . . . , h is a function parameter to be fitted, f(SOC) is an identified open circuit voltage OCV during the charging and discharging process of the battery, and SOC is the battery charging state;
a fitting unit, configured to fit the relational expression between the open circuit voltage OCV and the battery charging state by using a least square method to obtain a fitting value of the function parameter; and
a determination unit, configured to perform a secondary identification of the function parameter based on the relational expression between the open circuit voltage OCV and the battery charging state and the determined value range of the function parameter, to obtain the optimal parameter of the function parameter.

7. The battery temperature monitoring point identification and abnormality detection apparatus according to claim 6, wherein the determination unit is configured to:
process the second-order RC equivalent circuit model and the relational expression between the open circuit voltage OCV and the battery charging state within the value range of the function parameter by using a particle swarm algorithm, to perform the secondary identification of the function parameter, to obtain the optimal parameter of the function parameter.

8. The battery temperature monitoring point identification and abnormality detection apparatus according to claim 5, wherein the distance measurement unit comprises:
a total heat generated by the battery in the lumped heat transfer equation satisfies:
$${Q}_{total} = I * I * ( {R}_{0} + {R}_{1} + {R}_{2} ) + I * T * \frac{\partial E}{\partial T} ,$$
wherein I is a current of the battery, R₀ is an ohmic internal resistance of the battery, R₁ is an electrochemical polarization internal resistance of the battery, R₂ is a concentration polarization internal resistance of the battery, T is a temperature of the battery, and ∂E/∂T is a temperature entropy coefficient.

9. A non-transitory computer-readable storage medium, on which a computer program is stored, wherein the computer program, when executed by a processor, implements steps of the battery temperature monitoring point identification and abnormality detection method, wherein the method is applied to a battery module, a temperature sensor inside the battery module is determined as a temperature monitoring point of a battery, and the method comprises:
establishing a second-order RC equivalent circuit model of the battery in the battery module;
performing parameter identification on the second-order RC equivalent circuit model to obtain an optimal parameter; performing optimal parameter identification on the second-order RC equivalent circuit model by using a Kalman filter algorithm to identify a function parameter in a charging and discharging process of the battery;
obtaining distances between a plurality of temperature monitoring points in the battery module and the battery by using the obtained optimal parameter; establishing a lumped heat transfer equation of the battery by using the optimal parameter of the function parameter, and establishing a lumped heat transfer equation by using the optimal parameter and obtaining the distances between the temperature monitoring points in the battery module and the battery, wherein
the lumped heat transfer equation is expressed as:
$$ρ * {C}_{p} * \frac{dT}{dt} = \frac{{Q}_{total}}{V} + \frac{A * h * ( {T}_{amb} - T )}{V} + {\sum }_{i}^{n} λ \frac{( {T}_{i} - T )}{{dist}_{i}^{2}} ,$$
wherein ρ is an equivalent density of the battery, Cₚ is a specific heat capacity of the battery, dT is a temperature difference at a previous time instant, dt is a time difference between two time instants, Qₜₒₜₐₗ is a total heat generation of the battery, A is a surface area of the battery, h is a convection heat transfer coefficient, T_{amb} is an ambient temperature, T is a temperature of the battery, n is a quantity of the temperature monitoring points, λ is a thermal conductivity, Tᵢ is a temperature value measured by an i-th temperature monitoring point, distᵢ is a distance from the battery to the i-th temperature monitoring point; and
determining effectiveness of the temperature monitoring points based on an obtained distribution of the distances between the temperature monitoring points and the battery.
